(19) United States
(12) Patent Application Publication
(10) Pub. No.: US 2013/0181206 A1
(43) Pub. Date: Jul. 18, 2013

(54) ORGANIC EL DEVICE

(71) Applicants: Junichi Nagase, Ibaraki-shi (JP); Akinori Nishimura, Ibaraki-shi (JP); Hiroyuki Takemoto, Ibaraki-shi (JP)

(72) Inventors: Junichi Nagase, Ibaraki-shi (JP); Akinori Nishimura, Ibaraki-shi (JP); Hiroyuki Takemoto, Ibaraki-shi (JP)

(73) Assignee: NITTO DENKO CORPORATION, Ibaraki-shi, Osaka (JP)

(21) Appl. No.: 13/822,882

(22) PCT Filed: Sep. 13, 2011
(86) PCT No.: PCT/JP2011/070818

§ 371 Date: Mar. 13, 2013

(30) Foreign Application Priority Data
Sep. 21, 2010 (JP) 2010-210604

(51) Int. Cl. H01L 51/52

(52) U.S. Cl. CPC H01L 51/5275
USPC 257/40

(57) ABSTRACT

An organic EL device with a light diffusing element that includes a matrix containing a resin component and an ultrafine particle component, and a light diffusing fine particle dispersed in the matrix. Refractive indices of the resin component, the ultrafine particle component, and the light diffusing fine particle satisfy the following expression (1). Further, the light diffusing element includes a concentration adjusted area formed outside a vicinity of a surface of the light diffusing fine particle, in which a weight concentration of the resin component decreases and a weight concentration of the ultrafine particle component increases as a distance from the light diffusing fine particle increases.

|n_{P}−n_{A}|<|n_{P}−n_{B}| (1)

In the expression (1), n_{A} represents a refractive index of the resin component of the matrix, n_{B} represents a refractive index of the ultrafine particle component of the matrix, and n_{P} represents a refractive index of the light diffusing fine particle.

### TECHNICAL FIELD

The present invention relates to an organic EL device. More specifically, the present invention relates to an organic EL device including a light diffusing element.

### BACKGROUND ART

An organic electroluminescence (hereinafter also referred to as “organic EL”) device has a structure in which a number of layers such as a light emitting layer, an electron injection layer, an electron transport layer, a hole injection layer, a hole transport layer, a cathode, and an anode are laminated so as to maximize emission efficiency when supplied with a current and a voltage. In such a structure, a phase of exit light changes due to multiple interference at an interface of the respective layers, and color and brightness change depending upon a viewing angle. In order to solve such a problem, changing a material constituting each layer and a thickness thereof has been proposed (for example, Patent Literature 1). However, those changes also vary emission efficiency, and hence, there is a limit to the changes.

It is also known that light is confined in an organic EL device due to the above-mentioned multiple interference. In order to solve this problem, generally, there has been proposed a configuration in which a diffusion layer (for example, a microlens array) having a fine shape on a surface (for example, a shape in which fine voids are formed on a surface) is provided on an outermost layer of an organic EL device. However, such a fine shape has poor productivity because of difficulty in processing and is not suitable for a large organic EL device. Further, when voids formed on the surface of the diffusion layer are filled, diffusion performance is degraded. Therefore, the above-mentioned configuration is not suitable for outdoor use. A configuration using a diffusion plate containing fine particles as the diffusion layer has also been proposed. However, in the diffusion plate having such internal scattering, back scattering increases, and hence, light confined in the organic EL device cannot be extracted sufficiently.

### CITATION LIST

### Patent Literature

[PTL 1]: JP 2009-516902 A

### SUMMARY OF INVENTION

### Technical Problem

An object of the present invention is to provide an organic EL device which has enhanced light extraction efficiency and improved viewing angle dependence of brightness and color change, and a lighting device which uses the organic EL device.

### Solution to Problem

As a result of extensive studies, the inventors of the present invention found that the above-mentioned object can be achieved with the following organic EL device, to thereby complete the present invention.

According to an embodiment of the present invention, there is provided an organic EL device. The organic EL device includes: an organic EL element; and a light diffusing element arranged on a light emitting surface side of the organic EL element. The light diffusing element includes a matrix containing a resin component and an ultrafine particle component, and light diffusing fine particles dispersed in the matrix. Refractive indices of the resin component, the ultrafine particle component, and the light diffusing fine particle satisfy the following expression (1). Further, the light diffusing element includes a concentration adjusted area formed outside a vicinity of a surface of the light diffusing fine particle, in which a weight concentration of the resin component decreases and a weight concentration of the ultrafine particle component increases as a distance from the light diffusing fine particle increases.

|n_{P}−n_{A}|<|n_{P}−n_{B}| (1)

In the expression (1), n_{P}, represents a refractive index of the resin component of the matrix, n_{B} represents a refractive index of the ultrafine particle component of the matrix, and n_{P} represents a refractive index of the light diffusing fine particle.

In a preferred embodiment, the organic EL device further includes a second concentration adjusted area which is formed through permeation of the resin component into an inside of the vicinity of the surface of the light diffusing fine particle.

In another preferred embodiment, the light diffusing element has a haze of 90% to 99%.

In another preferred embodiment, the light diffusing element satisfies 0.01≦|n_{P}−n_{A}|≦0.10 and 0.10≦|n_{P}−n_{B}|≦1.50.

In another preferred embodiment, the resin component and the light diffusing fine particle are formed of materials of the same type, and the ultrafine particle component is formed of a material of a type different from the type of the resin component and the light diffusing fine particle.

In another preferred embodiment, the resin component and the light diffusing fine particle are formed of organic compounds, and the ultrafine particle component is formed of an inorganic compound.

In another preferred embodiment, the light diffusing fine particle has an average particle diameter of 1 μm to 5 μm.

In another preferred embodiment, the ultrafine particle component has an average particle diameter of 1 nm to 100 nm.

In another preferred embodiment, the light diffusing element has a diffusion half-value angle of 10° to 150°.

According to another embodiment of the present invention, a lighting device is provided. The lighting device includes the above-mentioned organic EL device.

### Advantageous Effects of Invention

The organic EL device according to an embodiment of the present invention includes a light diffusing element containing a concentration adjusted area (as a result, a refractive index adjusted area). Therefore, the direction of light can be changed by the refractive index adjusted area in the light diffusing element, and light in an oblique direction confined exceeding a critical angle can be extracted without generating any loss caused by scattering, which can enhance light extraction efficiency. Further, the presence of the refractive index adjusted area in the light diffusing element improves brightness and enables colors of light in various directions to be mixed. Thus, the brightness and color change for each viewing angle of the organic EL device can be suppressed. Further, the light diffusing element used in the present invention contains the refractive index adjusted area, and hence, can also be used preferably for products used outdoors.

### BRIEF DESCRIPTION OF DRAWINGS

FIG. 1 is a schematic cross-sectional view of an organic EL device in a preferred embodiment of the present invention.

FIG. 2A is a schematic view illustrating a dispersed state of a resin component and an ultrafine particle component of a matrix and light diffusing fine particles in a light diffusing element used in a preferred embodiment of the present invention.

FIG. 2B is a schematic view illustrating a dispersed state of a resin component and an ultrafine particle component of a matrix and light diffusing fine particles in a light diffusing element used in another embodiment of the present invention.

FIG. 3(a) is a conceptual view showing a change in a refractive index from a center portion of a light diffusing fine particle to a matrix in the light diffusing element of FIG. 2A; FIG. 3(b) is a conceptual view showing a change in a refractive index from a center portion of a light diffusing fine particle to a matrix in the light diffusing element of FIG. 2B; and FIG. 3(c) is a conceptual view showing a change in a refractive index from a center portion of a fine particle to a matrix in a conventional light diffusing element.

FIG. 4 is a schematic view showing a relationship between r1 and r2 in light diffusing fine particles used in a light diffusing element used in the present invention.

FIG. 5 is a graph showing a relationship between a drying temperature and a diffusion half-value angle to be obtained with regard to application liquids whose still standing times are different from each other.

FIG. 6 is a schematic cross-sectional view of an organic EL element used in the present invention.

FIG. 7 is a transmission photomicrograph in which the presence or absence of a concentration adjusted area is confirmed regarding a light diffusing element of Reference Example 1.

### DESCRIPTION OF EMBODIMENTS

<A. Brief Overview of an Organic EL Device>

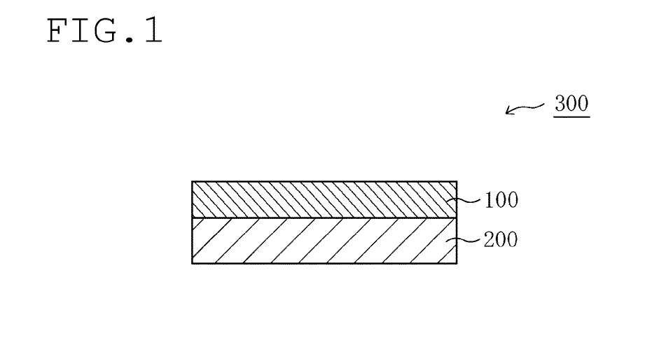

FIG. 1 is a schematic cross-sectional view of an organic EL device according to a preferred embodiment of the present invention. This organic EL device 300 includes an organic EL element 200 and a light diffusing element 100 placed on a light-emitting surface side of the organic EL element 200. By placing the light diffusing element 100 on an outermost layer of the organic EL device 300, light extraction efficiency from the organic EL device can be enhanced. Further, due to the presence of a concentration adjusted area of the light diffusing element 100, a change in color and brightness depending upon a viewing angle can be suppressed. Further, the light diffusing element 100 contains the concentration adjusted area, and hence, light extraction efficiency can be prevented from being degraded in outdoor use.

<B. Light Diffusing Element>

B-1. Entire Construction

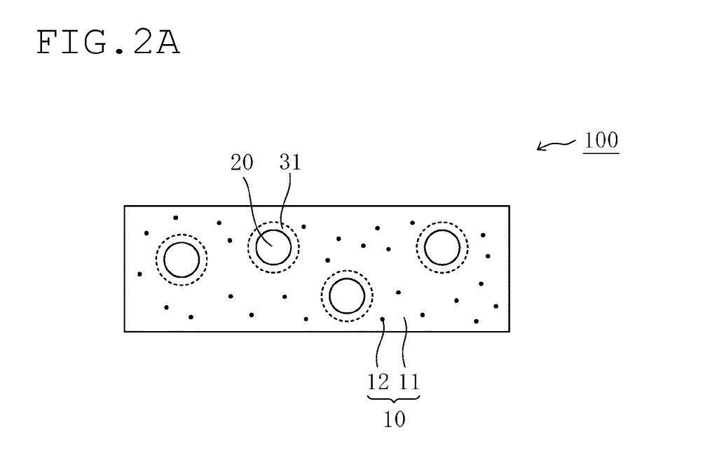

A light diffusing element used in the present invention includes a matrix containing a resin component and an ultrafine particle component, and light diffusing fine particles dispersed in the matrix. The light diffusing element used in the present invention expresses a light diffusing function due to the refractive index difference between the matrix and the light diffusing fine particles. FIGS. 2A and 2B are each a schematic view for illustrating a dispersed state of a resin component and an ultrafine particle component of a matrix, and light diffusing fine particles in a light diffusing element used in a preferred embodiment of the present invention. A light diffusing element 100 used in the present invention includes a matrix 10 containing a resin component 11 and an ultrafine particle component 12, and light diffusing fine particles 20 dispersed in the matrix 10. The refractive indices of the resin component and the ultrafine particle component of the matrix, and the light diffusing fine particles satisfy the following expression (1).

|n_{P}−n_{A}|<|n_{P}−n_{B}| (1)

In the expression (1), n_{A}, represents the refractive index of the resin component of the matrix, n_{B} represents the refractive index of the ultrafine particle component of the matrix, and n_{P} represents the refractive index of the light diffusing fine particles. Further, in the light diffusing element used in the present invention, the refractive indices of the resin component, the ultrafine particle component, and the light diffusing fine particles can also satisfy the following expression (2).

|n_{P}−n_{A}|<|n_{A}−n_{B}| (2)

In one embodiment, as shown in FIG. 2A, the light diffusing element used in the present invention has a concentration adjusted area 31 formed in an outer portion of the vicinity of the surface of each light diffusing fine particle 20. In another embodiment, as shown in FIG. 2B, the light diffusing element used in the present invention further has a second concentration adjusted area 32 formed by permeation of the resin component 11 to an inner portion of the vicinity of the surface of each light diffusing fine particle 20. In this description, for convenience, the concentration adjusted area 31 in the outer portion of the vicinity of the surface of the light diffusing fine particle 20 may be referred to as first concentration adjusted area.

In the case where only the first concentration adjusted area 31 is formed as shown in FIG. 2A, |n_{P}−n_{A}| in the above-mentioned expression (1) is preferably 0.0 to 0.1, more preferably 0.0 to 0.06, particularly preferably more than 0 and 0.06 or less. When |n_{P}−n_{A}| is more than 0.1, backscattering may increase, and brightness and light extraction efficiency in an oblique direction may be degraded. In the case where the first concentration adjusted area 31 and the second concentration adjusted area 32 are formed as shown in FIG. 2B, |n_{P}−n_{A}| in the above-mentioned expression (1) is preferably 0.01 to 0.10, more preferably 0.01 to 0.06, particularly preferably 0.02 to 0.06. When |n_{P}−n_{A}| is less than 0.01, the second concentration adjusted area may not be formed. When |n_{P}−n_{A}| is more than 0.10, backscattering may increase, and brightness and light extraction efficiency in an oblique direction may be degraded. Irrespective of whether the second concentration adjusted area 32 is formed, |n_{P}−n_{B}| is preferably 0.10 to 1.50, more preferably 0.20 to 0.80. When |ₙP−n_{B}| is less than 0.10, since colors of light cannot be satisfactorily mixed, color change depending on a viewing angle may not be suppressed and sufficient light extraction efficiency may not be obtained. When |n_{P}−n_{B}| is more than 1.50, backscattering may increase, and brightness and light extraction efficiency in an oblique direction may be degraded. Further, irrespective of whether the second concentration adjusted area 32 is formed, |n_{A}−n_{B}| is preferably 0.10 to 1.50, more preferably 0.20 to 0.80. When |n_{A}−n_{B}| is less than 0.10, since colors of light cannot be satisfactorily mixed, color change depending on a viewing angle may not be suppressed and sufficient light extraction efficiency may not be obtained. When |n_{P}−n_{B}| is more than 1.50, backscattering may increase, and brightness and light extraction efficiency in an oblique direction may be degraded. As described above, by using the resin component of the matrix and the light diffusing fine particles, the refractive indices of which are close to each other, and an ultrafine particle component whose refractive index is largely different from those of the resin component and the light diffusing fine particles in combination, backscattering can be suppressed, light extraction efficiency can be improved, and brightness change and color change depending on a viewing angle can be suppressed, together with the effects brought about by the first concentration adjusted area and the second concentration adjusted area described later.

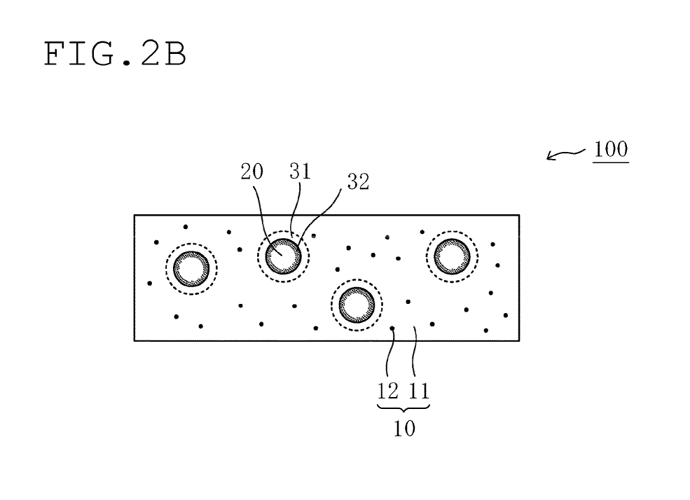

In the first concentration adjusted area 31, the weight concentration of the resin component 11 becomes lower and the weight concentration of the ultrafine particle component 12 becomes higher with increasing distance from the light diffusing fine particle 20. In other words, in an area closest to the light diffusing fine particle 20 of the first concentration adjusted area 31, the ultrafine particle component 12 is dispersed at a relatively low concentration, and the concentration of the ultrafine particle component 12 increases with increasing distance from the light diffusing fine particle 20. For example, in the area closest to the light diffusing fine particle 20 of the first concentration adjusted area 31, the weight concentration of the resin component is higher than the average weight concentration of the resin component in the entire matrix, and the weight concentration of the ultrafine particle component is lower than the average weight concentration of the ultrafine particle component in the entire matrix. On the other hand, in an area farthest from the light diffusing fine particle 20 of the first concentration adjusted area 31, the weight concentration of the resin component is equal to, or in some cases, lower than the average weight concentration of the resin component in the entire matrix, and the weight concentration of the ultrafine particle component is equal to, or in some cases, higher than the average weight concentration of the ultrafine particle component in the entire matrix. Due to the formation of such first concentration adjusted area, the refractive index can be changed in stages or substantially continuously in the vicinity of the interface (a circumferential portion of the light diffusing fine particle 20, that is, an outer portion of the vicinity of the surface of the light diffusing fine particle) between the matrix 10 and the light diffusing fine particle 20 (see FIG. 3(a)). On the other hand, in the conventional light diffusing element, such first concentration adjusted area is not formed, and the interface between the fine particle and the matrix is clear. Therefore, the refractive index changes discontinuously from the refractive index of the fine particles to the refractive index of the matrix (see FIG. 3(c)). As shown in FIG. 3(a), by forming the first concentration adjusted area 31 to change the refractive index in stages or substantially continuously in the vicinity of the interface (in an outer portion of the vicinity of the surface of the light diffusing fine particle 20) between the matrix 10 and the light diffusing fine particle 20, even when the refractive index difference between the matrix 10 and the light diffusing fine particle 20 is increased, the reflection at the interface between the matrix 10 and the light diffusing fine particle 20 can be suppressed, backscattering can be suppressed, light extraction efficiency can be improved, and brightness change and color change depending on a viewing angle can be suppressed. Further, on an outer side of the first concentration adjusted area 31, the weight concentration of the ultrafine particle component 12 whose refractive index is largely different from that of the light diffusing fine particle 20 becomes relatively high. Therefore, the refractive index difference between the matrix 10 and the light diffusing fine particle 20 can be increased. As a result, even a thin film can realize a high haze (strong diffusibility). Thus, according to the light diffusing element used in the present invention, by forming such first concentration adjusted area, backscattering can be suppressed, light extraction efficiency can be improved, and brightness change and color change depending on a viewing angle can be suppressed. On the other hand, as shown in FIG. 3(c), according to the conventional light diffusing element, when an attempt is made to give strong diffusibility (high haze value) by increasing a refractive index difference, the gap between refractive indices at an interface cannot be eliminated. Consequently, backscattering caused by interface reflection increases, sufficient light extraction efficiency cannot be obtained and brightness change and color change depending on a viewing angle may occur.

The thickness of the first concentration adjusted area 31 (distance from the surface of the light diffusing fine particle to the end of the first concentration adjusted area) may be constant (that is, the first concentration adjusted area may spread to the circumference of the light diffusing fine particle in a concentric circle shape), or the thickness may vary depending upon the position of the surface of the light diffusing fine particle (for example, the first concentration adjusted area may have a contour shape of a candy called confetti). Preferably, the thickness of the first concentration adjusted area 31 may vary depending upon the position of the surface of the light diffusing fine particle. With such construction, the refractive index can be changed more continuously in the vicinity of the interface between the matrix 10 and the light diffusing fine particle 20. As long as the first concentration adjusted area 31 is formed with a sufficient thickness, the refractive index can be changed more smoothly and continuously in a circumferential portion of the light diffusing fine particle, backscattering can be suppressed, light extraction efficiency can be improved, and brightness change and color change depending on a viewing angle can be suppressed. On the other hand, when the thickness is too large, the first concentration adjusted area occupies an area in which the light diffusing fine particle should be originally present, and sufficient light diffusibility (for example, a haze value) may not be obtained. Thus, the thickness of the first concentration adjusted area 31 is preferably 10 nm to 500 nm, more preferably 20 nm to 400 nm, still more preferably 30 nm to 300 nm. Further, the thickness of the first concentration adjusted area 31 is preferably 10% to 50%, more preferably 20% to 40% with respect to the average particle diameter of the light diffusing fine particle.

The second concentration adjusted area 32 is formed by permeation of the resin component 11 to an inner portion of the light diffusing fine particle 20. Virtually, a precursor (typically, a monomer) of the resin component 11 permeates an inner portion of the light diffusing fine particle 20 to be polymerized, and thus, the second concentration adjusted area 32 is formed. In one embodiment, the weight concentration of the resin component 11 is substantially constant in the second concentration adjusted area 32. In another embodiment, in the second concentration adjusted area 32, the weight concentration of the resin component 11 becomes lower with increasing distance from the surface of the light diffusing fine particle 20 (that is, toward the center of the light diffusing fine particle 20). The second concentration adjusted area 32 exhibits its effect as long as the second concentration adjusted area 32 is formed inside the light diffusing fine particle 20. For example, the second concentration adjusted area 32 is formed in the range of preferably 10% to 95% of an average particle diameter of the light diffusing fine particle from the surface of the light diffusing fine particle 20. The thickness of the second concentration adjusted area 32 (distance from the surface of the light diffusing fine particle to the innermost portion of the second concentration adjusted area) may be constant or may vary depending upon the position of the surface of the light diffusing fine particle. The thickness of the second concentration adjusted area 32 is preferably 100 nm to 4 μm, more preferably 100 nm to 2 μm. When the resin component 11 permeates an inner portion of the light diffusing fine particle to form the second concentration adjusted area 32, the following effects can be obtained: (1) the formation of the above-mentioned first concentration adjusted area 31 can be accelerated; (2) a concentration adjusted area is also formed in an inner portion of the light diffusing fine particle, and thus, an area in which the refractive index is changed in stages or substantially continuously can be enlarged (that is, the refractive index can be changed in stages or substantially continuously from the second concentration adjusted area on an inner side of the light diffusing fine particle to the first concentration adjusted area on an outer side of the light diffusing fine particle: see FIG. 3(b)). As a result, compared with the case where only the first concentration adjusted area is formed on an outer side of the light diffusing fine particle, backscattering can be further suppressed, light extraction efficiency can be further improved, and brightness change and color change depending on a viewing angle can be suppressed; (3) the resin component 11 permeates an inner portion of the light diffusing fine particle 20, and thus, the concentration of a resin component in the matrix 10 becomes lower compared with the case where the resin component does not permeate the inner portion of the light diffusing fine particle. As a result, the contribution of the refractive index of the ultrafine particle component 12 with respect to the refractive index of the entire matrix 10 increases, and hence, the refractive index of the entire matrix becomes large in the case where the refractive index of the ultrafine particle component is large (on the contrary, the refractive index of the entire matrix becomes small in the case where the refractive index of the ultrafine particle component is small), and the refractive index difference between the matrix and the light diffusing fine particle becomes larger. Thus, compared with the case where the resin component does not permeate the inner portion of the light diffusing fine particle, higher diffusibility (haze value) can be realized. In addition, compared with the case where the resin component does not permeate the inner portion of the light diffusing fine particle, sufficient diffusibility can be realized even with a smaller thickness.

The first concentration adjusted area and second concentration adjusted area can each be formed by selecting appropriately the constituent material and chemical and thermodynamic properties of the resin component, the ultrafine particle component of the matrix, and the light diffusing fine particle. For example, by forming the resin component and the light diffusing fine particles from materials of the same type (e.g., organic compounds), and forming the ultrafine particle component from a material (e.g., an inorganic compound) of a different type from those of the matrix and the light diffusing fine particles, the first concentration adjusted area can be formed satisfactorily. Further, for example, by forming the resin component and the light diffusing fine particles from materials that are highly compatible among materials of the same type, the second concentration adjusted area can be formed satisfactorily. The thickness and the concentration gradient of the first concentration adjusted area and the second concentration adjusted area can be controlled by adjusting the chemical and thermodynamic properties of the resin component and the ultrafine particle component of the matrix and the light diffusing fine particles. It should be noted that the term “same type” as used herein means that the chemical structures and properties are identical or similar to each other, and the term “different type” refers to one other than the same type. Whether materials are of the same type or not may vary depending upon ways to select standards. For example, in the case where materials are selected based on an organic or inorganic material, organic compounds are compounds of the same type, and an organic compound and an inorganic compound are compounds of different types. In the case where materials are selected based on a repeating unit of a polymer, for example, an acrylic polymer and an epoxy-based polymer are compounds of different types, although they are organic compounds. In the case where materials are selected based on the periodic table, an alkali metal and a transition metal are elements of different types, although they are inorganic elements.

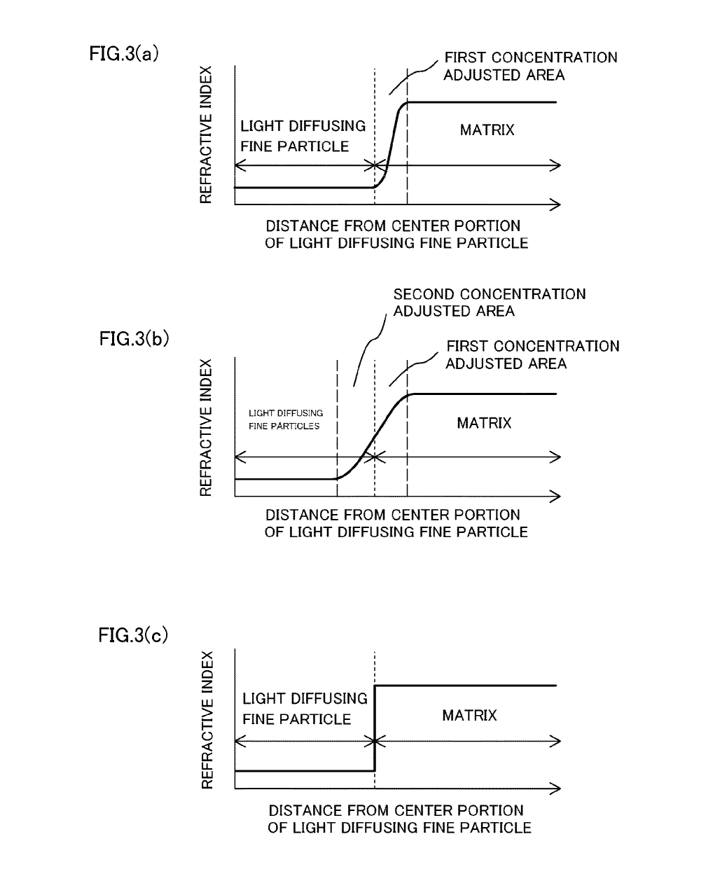

The first concentration adjusted area 31 and second concentration adjusted area 32 are appropriately formed at such positions that, when a radius of each of the light diffusing fine particles is defined as r1 and a radius of a cross-section parallel to the maximum cross-section (plane including the radius of each of the light diffusing particles) of each of the light diffusing fine particles is defined as r2, a ratio of r2 to r1 is preferably 20% to 80%, more preferably 40% to 60%, still more preferably about 50%. By appropriately forming the first concentration adjusted area 31 and the second concentration adjusted area 32, if required, at such positions, the interface reflection of incident light (hereinafter, referred to as lateral incident light) with a large incident angle with respect to a radial direction of the light diffusing fine particles can be suppressed satisfactorily. FIG. 4 schematically shows the relationship between r1 and r2. More specifically, backscattering caused by the interface reflection between the matrix and the light diffusing fine particles is roughly classified into three kinds as shown in FIG. 4. That is, the backscattering is classified into the interface reflection light of front incidence (arrow A of FIG. 4), the interface reflection light of lateral incident light scattering backward (arrow B of FIG. 4), and the interface reflection light of lateral incident light that scatters forward but scatters backward without being output from the light diffusing element due to the total reflection (arrow C of FIG. 4). The lateral incident light has a reflectance higher than that of front incident light based on the Snell's law, and hence, backscattering can be reduced more efficiently by suppressing the interface reflection of lateral incident light. Thus, it is preferred that a concentration adjusted area be formed at such a position that the backscattering of lateral incident light can be reduced effectively. When r2 is too small, light reflected at such position is transmitted forward without reaching a critical angle. Therefore, the effect of reducing backscattering is not significantly influenced in most cases.

It is preferred that the light diffusing element has a haze as high as possible. Specifically, the haze is preferably 90% to 99%, more preferably 92% to 99%, still more preferably 95% to 99%, particularly preferably 97% to 99%. When the haze is 90% or more, light is scattered, and colors of light in various directions can be mixed and consequently color change can be suppressed. Further, light in an oblique direction is extracted so that brightness can be improved.

The diffusion property of the light diffusing element is preferably 10° to 150° (5° to 75° on one side), more preferably 10° to 100° (5° to 50° on one side), still more preferably 30° to 80° (15° to 40° on one side) in terms of a light diffusion half-value angle.

The thickness of the light diffusing element can be set appropriately depending upon purposes and desired diffusion property. Specifically, the thickness of the light diffusing element is preferably 4 μm to 50 μm, more preferably 4 μm to 20 μm. In the present invention, a light diffusing element having a very high haze as described above in spite of such very small thickness can be preferably used.

B-2. Matrix

As described above, the matrix 10 includes the resin component 11 and the ultrafine particle component 12. As shown in FIGS. 2A and 2B, the ultrafine particle component 12 is dispersed in the resin component 11 so as to form the first concentration adjusted area 31 around the light diffusing fine particle 20.

B-2-1. Resin Component

The resin component 11 is formed of any suitable material as long as the first concentration adjusted area, and if required, the second concentration adjusted area are formed satisfactorily, and the refractive indices satisfy the relationship of the above-mentioned expression (1). Preferably, as described above, the resin component 11 is formed of a compound that is of the same type as that of the light diffusing fine particles and that is of a different type from that of the ultrafine particle component. Thus, the first concentration adjusted area can be formed satisfactorily in the vicinity of the interface between the matrix and the light diffusing fine particles (in an outer portion of the vicinity of the surface of each of the light diffusing fine particles). More preferably, the resin component 11 is formed of a compound having high compatibility among those of the same type as that of the light diffusing fine particles. Thus, the second concentration adjusted area 32 can be formed satisfactorily in an inner portion of the vicinity of the surface of each of the light diffusing fine particles 20, if required. More specifically, the resin component is a material of the same type as that of the light diffusing fine particles, and hence a precursor thereof (typically, a monomer) can permeate the inner portion of the light diffusing fine particles. As the result of the polymerization of the precursor, the second concentration adjusted area with the resin component can be formed inside the light diffusing fine particles. Further, locally in the vicinity of the light diffusing fine particles, when only the resin component surrounds the light diffusing fine particles, the energy of the entire system becomes stable, compared with the case where the ultrafine particle component is uniformly dissolved or dispersed in the resin component. As a result, the weight concentration of the resin component becomes higher than the average weight concentration of the resin component in the entire matrix, and becomes lower with increasing distance from the light diffusing fine particles, in an area closest to the light diffusing fine particles. Thus, the first concentration adjusted area 31 can be formed in an outer portion of (around) the vicinity of the surface of the light diffusing fine particles.

The resin component is formed of preferably an organic compound, more preferably an ionizing radiation-curable resin. The ionizing radiation-curable resin is excellent in hardness of a coating film, and hence easily compensates for mechanical strength, which is a weak point of the ultrafine particle component described later. Examples of the ionizing radiation include UV light, visible light, infrared light, and electron beam. Of those, UV light is preferred, and thus, the resin component is particularly preferably formed of a UV-curable resin. Examples of the UV-curable resin include radical-polymerizable monomers and oligomers such as an acrylate resin (epoxy acrylate, polyester acrylate, acrylic acrylate, or ether acrylate). A monomer component (precursor) that constructs the acrylate resin preferably has a molecular weight of 200 to 700. Specific examples of the monomer component (precursor) that constructs the acrylate resin include pentaerythritol triacrylate (PETA, molecular weight: 298), neopentylglycol diacrylate (NPGDA, molecular weight: 212), dipentaerythritol hexaacrylate (DPHA, molecular weight: 632), dipentaerythritol pentaacrylate (DPPA, molecular weight: 578), and trimethylolpropane triacrylate (TMPTA, molecular weight: 296). Such monomer component (precursor) is preferred due to its molecular weight and steric structure suitable for permeation to a cross-linked structure (three-dimensional network structure) of the light diffusing fine particles. If required, an initiator may be added. Examples of the initiator include a UV radical generator (e.g., Irgacure 907, 127, or 192 manufactured by Ciba Specialty Chemicals) and benzoyl peroxide. The resin component may contain another resin component other than the above-mentioned ionizing radiation-curable resin. The another resin component may be an ionizing radiation-curable resin, a thermosetting resin, or a thermoplastic resin. Typical examples of the another resin component include an aliphatic (for example, polyolefin) resin and a urethane-based resin. In the case of using the another resin component, the kind and blending amount thereof are adjusted so that the first concentration adjusted area, and if required, the second concentration adjusted area are formed satisfactorily, and the refractive indices satisfy the relationship of the above-mentioned expression (1).

The refractive index of the resin component is preferably 1.40 to 1.60.

The blending amount of the resin component is preferably 20 parts by weight to 80 parts by weight, more preferably 40 parts by weight to 65 parts by weight with respect to 100 parts by weight of the matrix.

B-2-2. Ultrafine Particle Component

As described above, the ultrafine particle component 12 is formed of preferably a compound of a different type from those of the resin component described above and the light diffusing fine particles described later, more preferably an inorganic compound. Preferred examples of the inorganic compound include a metal oxide and a metal fluoride. Specific examples of the metal oxide include zirconium oxide (zirconia) (refractive index: 2.19), aluminum oxide (refractive index: 1.56 to 2.62), titanium oxide (refractive index: 2.49 to 2.74), and silicon oxide (refractive index: 1.25 to 1.46). Specific example of the metal fluoride include magnesium fluoride (refractive index: 1.37) and calcium fluoride (refractive index: 1.40 to 1.43). These metal oxides and metal fluorides absorb less light and each have a refractive index which is difficult to be expressed with organic compounds such as the ionizing radiation-curable resin and the thermoplastic resin. Therefore, the weight concentration of the ultrafine particle component becomes relatively higher with increasing distance from the interface with the light diffusing fine particles, and thus, the metal oxides and metal fluorides can change the refractive index largely. By setting a refractive index difference between the light diffusing fine particles and the matrix to be large, a high haze can be realized even with a thin film, and the effect of preventing backscattering is large because the first concentration adjusted area is formed. Further, light extraction efficiency of the organic EL device can be improved, and brightness change and color change depending on a viewing angle can be suppressed. Zirconium oxide is a particularly preferred inorganic compound. This is because zirconium oxide has a large refractive index difference from the light diffusing fine particles, and has appropriate dispersibility with respect to the resin component, which enables the first concentration adjusted area 31 to be formed in a desirable manner.

The refractive index of the ultrafine particle component is preferably 1.40 or less or 1.60 or more, more preferably 1.40 or less or 1.70 to 2.80, particularly preferably 1.40 or less or 2.00 to 2.80. When the refractive index is more than 1.40 or less than 1.60, the refractive index difference between the light diffusing fine particles and the matrix becomes insufficient, and sufficient light extraction efficiency may not be obtained.

The refractive index may be decreased by porosifying the ultrafine particle component.

The average particle diameter of the ultrafine particle component is preferably 1 nm to 100 nm, more preferably 10 nm to 80 nm, still more preferably 20 nm to 70 nm. As described above, by using the ultrafine particle component with an average particle diameter smaller than the wavelength of light, geometric reflection, refraction, and scattering are not caused between the ultrafine particle component and the resin component, and a matrix that is optically uniform can be obtained. As a result, a light diffusing element that is optically uniform can be obtained.

It is preferred that the ultrafine particle component has satisfactory dispersibility with the resin component. The term “satisfactory dispersibility” as used herein means that a coating film, which is obtained by coating an application liquid containing the resin component, the ultrafine particle component (if required, a small amount of a UV initiator), and a volatile solvent, followed by removing the solvent by drying, is transparent.

Preferably, the ultrafine particle component is subjected to surface modification. By conducting surface modification, the ultrafine particle component can be dispersed satisfactorily in the resin component, and the first concentration adjusted area can be formed satisfactorily. As surface modification means, any suitable means can be adopted as long as the effect of the present invention is obtained. Typically, the surface modification is conducted by coating a surface modifier onto the surface of an ultrafine particle component to form a surface modifier layer. Preferred specific examples of the surface modifier include coupling agents such as a silane-based coupling agent and a titanate-based coupling agent, and a surfactant such as a fatty acid-based surfactant. By using such surface modifier, the wettability between the resin component and the ultrafine particle component is enhanced, the interface between the resin component and the ultrafine particle component is stabilized, the ultrafine particle component is dispersed satisfactorily in the resin component, and the first concentration adjusted area can be formed satisfactorily.

The blending amount of the ultrafine particle component is preferably 10 parts by weight to 70 parts by weight, more preferably 35 parts by weight to 60 parts by weight with respect to 100 parts by weight of the matrix.

B-3. Light Diffusing Fine Particles

The light diffusing fine particles 20 are also formed of any suitable material, as long as the first concentration adjusted area, and if required, the second concentration adjusted area are formed satisfactorily, and the refractive indices satisfy the relationship of the above-mentioned expression (1). Preferably, as described above, the light diffusing fine particles 20 are formed of a compound of the same type as that of the resin component of the matrix. For example, in the case where the ionizing radiation-curable resin that constructs the resin component of the matrix is an acrylate-based resin, it is preferred that the light diffusing fine particles be also constructed of the acrylate-based resin. More specifically, when the monomer component of the acrylate-based resin that constructs the resin component of the matrix is, for example, PETA, NPGDA, DPHA, DPPA, and/or TMPTA as described above, the acrylate-based resin that constructs the light-diffusing fine particles is preferably polymethyl methacrylate (PMMA), polymethyl acrylate (PMA), or a copolymer thereof, or a cross-linked product thereof. A copolymerizable component for each of PMMA and PMA is, for example, polyurethane, polystyrene (PSt), or a melamine resin. Particularly preferably, the light diffusing fine particles are constructed of PMMA. This is because the relationship in refractive index and thermodynatic properties with respect to the resin component of the matrix and the ultrafine particle component is suitable. Further, preferably, the light diffusing fine particles have a cross-linked structure (three-dimensional network structure). The light diffusing fine particles having a cross-linked structure are capable of being swollen. Thus, such light diffusing fine particles allow a precursor of a resin component having suitable compatibility to permeate an inner portion thereof satisfactorily, unlike dense or solid inorganic particles, and can satisfactorily form the second concentration adjusted area, if required. The cross-linking density of the light diffusing fine particles is preferably small (rough) to such a degree that a desired permeation range (described later) is obtained. For example, the swelling degree of the light diffusing fine particles at the time of coating an application liquid described later with respect to the resin component precursor (which may contain a solvent) is preferably 110% to 200%. Here, the term “swelling degree” refers to a ratio of an average particle diameter of the particles in a swollen state with respect to the average particle diameter of the particles before being swollen.

The average particle diameter of the light diffusing fine particles is preferably 1.0 μm to 5.0 μm, more preferably 1.0 μm to 4.0 μm, still more preferably 1.5 μm to 3.0 μm. The average particle diameter of the light diffusing fine particles is preferably ½ or less (for example, ½ to 1/20) of the thickness of the light diffusing element. As long as the light diffusing fine particles have an average particle diameter having such ratio with respect to the thickness of the light diffusing element, a plurality of light diffusing fine particles can be arranged in a thickness direction of the light diffusing element. Therefore, while incident light is passing through the light diffusing element, the incident light can be diffused in a multiple manner, and consequently, sufficient light diffusibility can be obtained.

The standard deviation of a weight average particle diameter distribution of the light diffusing fine particles is preferably 1.0 μm or less, more preferably 0.5 μm or less. When the light diffusing fine particles each having a small particle diameter with respect to the weight average particle diameter are present in a large number, the diffusibility may increase too much to suppress backscattering satisfactorily. When the light diffusing fine particles each having a large particle diameter with respect to the weight average particle diameter are present in a large number, a plurality of the light diffusing fine particles cannot be arranged in a thickness direction of the light diffusing element, and multiple diffusion may not be obtained. As a result, the light diffusibility may become insufficient, and sufficient light extraction efficiency may not be obtained.

As the shape of the light diffusing fine particles, any suitable shape can be adopted depending upon the purpose. Specific examples thereof include a spherical shape, a scalelike shape, a plate shape, an oval shape, and an amorphous shape. Inmost cases, spherical fine particles can be used as the light diffusing fine particles.

The refractive index of the light diffusing fine particles is preferably 1.30 to 1.70, more preferably 1.40 to 1.60.

The blending amount of the light diffusing fine particles is preferably 10 parts by weight to 100 parts by weight, more preferably 15 parts by weight to 40 parts by weight with respect to 100 parts by weight of the matrix. For example, by allowing the light diffusing fine particles having an average particle diameter in the above-mentioned preferred range to be contained in such blending amount, a light diffusing element having very excellent light diffusibility can be obtained.

B-4. Manufacturing Method for Light Diffusing Element

A manufacturing method for a light diffusing element used in the present invention includes the steps of: coating an application liquid, in which a resin component or a precursor thereof and an ultrafine particle component of a matrix, and light diffusing fine particles are dissolved or dispersed in a volatile solvent, onto a base material (defined as Step A); and drying the application liquid coated onto the base material (defined as Step B).

(Step A)

The resin component or precursor thereof, the ultrafine particle component, and the light diffusing fine particles are as described in the above-mentioned sections B-2-1, B-2-2, and B-3. Typically, the application liquid is a dispersion in which the ultrafine particle component and the light diffusing fine particles are dispersed in the precursor and the volatile solvent. As means for dispersing the ultrafine particle component and the light diffusing fine particles, any suitable means (for example, ultrasound treatment) can be adopted.

Any suitable solvent can be adopted as the volatile solvent as long as the solvent can dissolve or uniformly disperse each component described above. Specific examples of the volatile solvent include ethyl acetate, butyl acetate, isopropyl acetate, 2-butanone (methyl ethyl ketone), methyl isobutyl ketone, cyclopentanone, toluene, isopropyl alcohol, n-butanol, cyclopentane, and water.

The application liquid can further contain any suitable additive depending upon the purpose. For example, in order to disperse the ultrafine particle component satisfactorily, a dispersant can be preferably used. Other specific examples of the additive include an antioxidant, a modifying agent, a surfactant, a discoloration inhibitor, a UV absorbing agent, a leveling agent, and an antifoaming agent.

The blending amount of each component described above in the application liquid is as described in the above-mentioned sections B-2 to B-3. The solid content of the application liquid can be adjusted so as to be preferably about 10% by weight to 70% by weight. With such solid content, an application liquid having a viscosity that facilitates coating can be obtained.

Any suitable film can adopted as the base material as long as the effects of the present invention can be provided. Specific examples thereof include a triacetyl cellulose (TAC) film, a polyethylene terephthalate (PET) film, a polypropylene (PP) film, a nylon film, an acrylic film, and a lactone-modified acrylic film. The base material may be subjected to surface modification such as adhesion enhancing treatment, or may include an additive such as a lubricant, an antistat, or a UV absorbing agent, as required. The base material may function as a protective layer in a polarizing plate with a light diffusing element described later.

Any suitable method using a coater can be adopted as a method of coating the application liquid onto the base material. Specific examples of the coater include a bar coater, a reverse coater, a kiss coater, a gravure coater, a die coater, and a comma coater.

(Step B)

As the method of drying the application liquid, any suitable method can be adopted. Specific examples thereof include natural drying, drying by heating, and drying under reduced pressure. Drying by heating is preferred. The heating temperature is, for example, 60° C. to 150° C., and the heating time is, for example, 30 seconds to 5 minutes.

As described above, a light diffusing element as shown in FIG. 2A is formed on a base material.

In the case of forming the second concentration adjusted area inside the light diffusing fine particles as shown in FIG. 2B, the manufacturing method of the present invention further includes, in Step A, the steps of bringing the precursor of the resin component described above into contact with the light diffusing fine particles in the application liquid (defined as Step A-1), and allowing at least a part of the precursor to permeate an inner portion of the light diffusing fine particles (defined as Step A-2).

(Step A-1)

If the precursor of the resin component described above is contained in the application liquid, the contact between the precursor and the light diffusing fine particles can be realized without special treatments or operations.

(Step A-2)

As means for allowing at least apart of the precursor to permeate an inner portion of the light diffusing fine particles in Step A-2, typically, there is given means including allowing the application liquid to stand still. As the resin component and the light diffusing fine particles are formed of preferably materials of the same type, more preferably materials having high compatibility with each other, the precursor (monomer) of the resin component is allowed to permeate an inner portion of the light diffusing fine particles by allowing the application liquid to stand still, even without any special treatments or operations. Specifically, by bringing the precursor of the resin component into contact with the light diffusing fine particles for a predetermined period of time, the precursor of the resin component permeates the inner portion of the light diffusing fine particles. The still standing time is preferably longer than a time in which the particle diameter of each of the light diffusing fine particles becomes substantially maximum. Here, the “time in which the particle diameter of each of the light diffusing fine particles becomes substantially maximum” refers to a time in which the light diffusing fine particles are each swollen to a maximum degree and are not swollen any more (that is, an equilibrium state) (hereinafter, also referred to as maximum swelling time). By bringing the precursor of the resin component into contact with the light diffusing fine particles over a period of time longer than the maximum swelling time, the permeation of the resin component precursor into the light diffusing fine particles is saturated, and the precursor is not taken in the cross-linking structure inside the light diffusing fine particles any more. As a result, the second concentration adjusted area can be formed satisfactorily and stably in a polymerization step described later. The maximum swelling time can vary depending upon the compatibility between the resin component and the light diffusing fine particles. Thus, the still standing time can vary depending upon the constituent materials for the resin component and the light diffusing fine particles. For example, the still standing time is preferably 1 to 48 hours, more preferably 2 to 40 hours, still more preferably 3 to 35 hours, particularly preferably 4 to 30 hours. When the still standing time is less than 1 hour, the precursor may not permeate the inner portion of the light diffusing fine particles sufficiently, and as a result, the second concentration adjusted area may not be formed satisfactorily. When the still standing time exceeds 48 hours, due to the physical interaction among the light diffusing fine particles, the light diffusing fine particles coagulate to increase the viscosity of the application liquid, which may render the coating property insufficient. Still standing may be conducted at room temperature, or under predetermined temperature conditions set in accordance with the purpose and materials to be used.

In Step A-2, the precursor has only to permeate a part of the light diffusing fine particles from the surfaces of the light diffusing fine particles, and for example, permeates preferably in a range of 10% to 95% of the average particle diameter. When the permeation range is less than 10%, the second concentration adjusted area may not be formed satisfactorily and backscattering may not be reduced sufficiently. Even when the permeation range exceeds 95%, the second concentration adjusted area may not be formed satisfactorily and backscattering may not be reduced sufficiently in the same way as in the case where the permeation range is small. The permeation range can be controlled by adjusting the materials for the resin component and the light diffusing fine particles, the cross-linking density of the light diffusing fine particles, the still standing time, the still standing temperature, or the like.

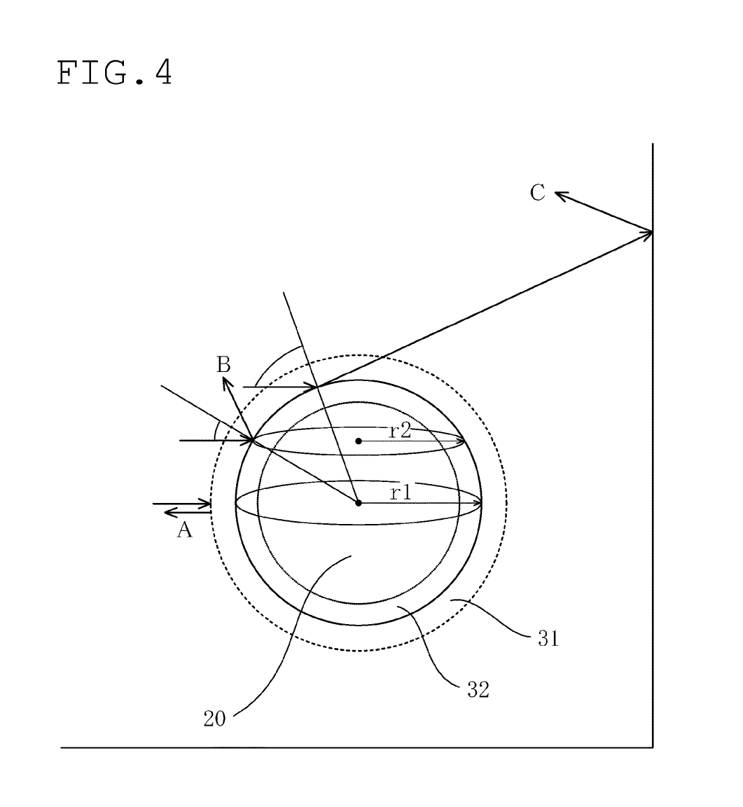

In this embodiment, it is important to control the permeation of the precursor into the light diffusing fine particles. For example, as shown in FIG. 5, in the case of forming a light diffusing element by coating the application liquid to a base material immediately after preparing the application liquid, a diffusion half-value angle largely varies depending upon the drying temperature. On the other hand, in the case of forming a light diffusing element by coating the application liquid to a base material after allowing the application liquid to standstill for, for example, 24 hours, the diffusion half-value angle remains almost constant irrespective of the drying temperature. The reason for this is considered as follows: the precursor permeates the light diffusing fine particles to a saturated state due to the still standing, and hence, the formation of the concentration adjusted area is not influenced by the drying temperature. Thus, as described above, the still standing time is preferably longer than the maximum swelling time. By setting the still standing time as such, a satisfactory diffusion half-value angle that remains almost constant irrespective of the dying time can be obtained, and hence, a light diffusing element with high diffusibility can be produced stably without variations. Further, a light diffusing element can be manufactured by drying at a low temperature of 60° C., for example, and this is preferred in terms of safety and cost. On the other hand, if the time required for the permeation to reach a saturated state can be determined depending upon the kinds of the precursor and the light diffusing fine particles, a light diffusing element with high diffusibility can be produced stably without variations even when shortening the still standing time, by selecting the drying temperature appropriately. For example, even in the case of forming a light diffusing element by coating the application liquid to a base material immediately after preparing the application liquid, a light diffusing element with high diffusibility can be produced stably without variations by setting the drying temperature to be 100° C. More specifically, if the light diffusing fine particles, the precursor of the resin component, and the drying conditions are selected appropriately, the second concentration adjusted area can be formed even without taking the still standing time.

As described above, in each of Steps A-1 and A-2, special treatments or operations are not required, and hence, it is not necessary to set a timing for coating an application liquid precisely.

(Step C)

In the case of forming the second concentration adjusted area, the manufacturing method further includes preferably the step of polymerizing the above-mentioned precursor after the application step (Step C). As the polymerization method, any suitable method can be adopted depending upon the kind of the resin component (thus, the precursor thereof). For example, in the case where the resin component is an ionizing radiation-curable resin, the precursor is polymerized by emitting ionizing radiation. In the case of using UV light as the ionizing radiation, the integrated light quantity is preferably 200 mJ to 400 mJ. The transmittance of the ionizing radiation with respect to the light diffusing fine particles is preferably 70% or more, more preferably 80% or more. Further, for example, in the case where the resin component is a thermosetting resin, the precursor is polymerized by heating. The heating temperature and the heating time can be set appropriately depending upon the kind of the resin component. Preferably, the polymerization is conducted by emitting ionizing radiation. The ionizing radiation can cure a coating film while keeping the refractive index distribution structure (concentration adjusted area) satisfactorily, and hence, a light diffusing element with satisfactory diffusing properties can be manufactured. By polymerizing the precursor, the second concentration adjusted area 32 is formed in an inner portion of the vicinity of the surface of the light diffusing fine particles 20, and the matrix 10 and the first concentration adjusted area 31 are formed. More specifically, the second concentration adjusted area 32 is formed when the precursor having permeated an inner portion of the light diffusing fine particles 20 is polymerized, and the matrix 10 is formed when the precursor that has not permeated the light diffusing fine particles 20 is polymerized with the ultrafine particle component dispersed therein. The first concentration adjusted area 31 can be formed mainly based on the compatibility among the resin component, the ultrafine particle component, and the light diffusing fine particles. That is, according to the manufacturing method of this embodiment, by polymerizing both the precursor that has permeated an inner portion of the light diffusing fine particles and the precursor that has not permeated the light diffusing fine particles simultaneously, the second concentration adjusted area 32 is formed in an inner portion of the vicinity of the surface of the light diffusing fine particles 20, and at the same time, the matrix 10 and the first concentration adjusted area 31 can be formed.

The polymerization step (Step C) may be conducted before the drying step (Step B) or after Step B.

It should be appreciated that the manufacturing method for a light diffusing element used in the present invention can include, in addition to Steps A to C, any suitable steps, treatments and/or operations at any suitable times. The kind of such steps and the like and the time when such steps and the like are conducted can be set appropriately depending upon the purpose.

As described above, the light dispersing element as described in the sections B-1 to B-3 is formed on a base material. The obtained light diffusing element may be used after being peeled from the base material for use as a single member, or may be used as a light diffusing element with a base material.

<C. Organic Electroluminescence Element (Organic EL Element)>

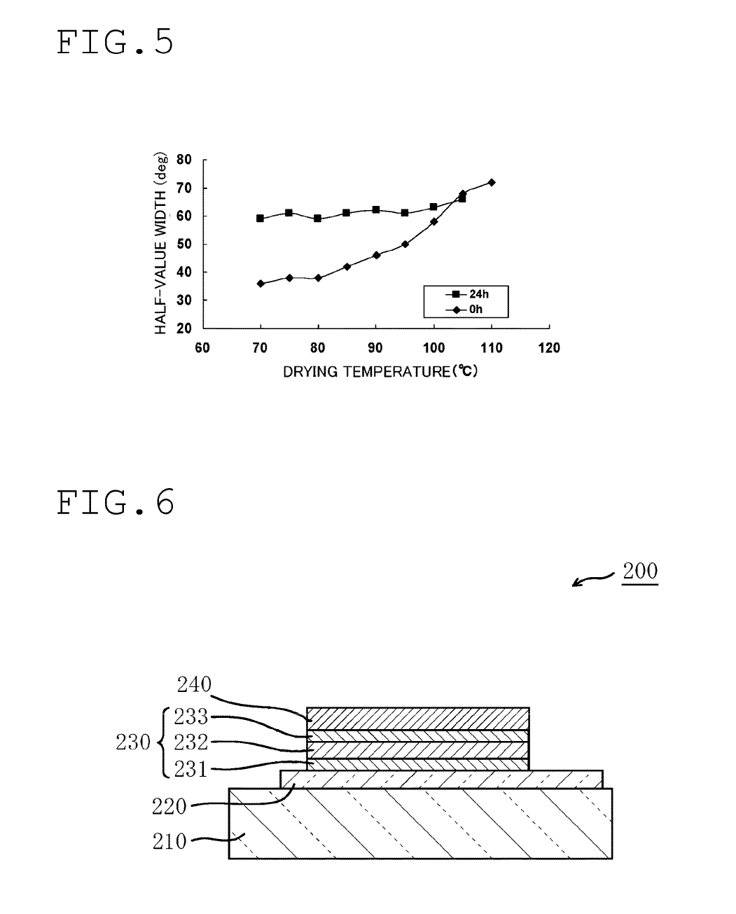

FIG. 6 is a schematic cross-sectional view of an organic EL element according to a preferred embodiment of the present invention. The organic EL element 200 includes a transparent substrate 210, and a transparent electrode 220, an organic EL layer 230, and a counter electrode 240 formed on the transparent substrate 210 in order.

In the organic EL element, in order to extract light emitted from the organic EL layer 230, it is required that at least one electrode (typically, an anode) be transparent. As a material for forming the transparent electrode, there are used, for example, indium tin oxide (ITO), indium zinc oxide (IZO), indium tin oxide containing silicon oxide (ITSO), indium oxide containing tungsten oxide (IWO), indium zinc oxide containing tungsten oxide (IWZO), indium oxide containing titanium oxide (ITiO), indium tin oxide containing titanium oxide (ITTiO), and indium tin oxide containing molybdenum (ITMO). On the other hand, in order to facilitate the injection of electrons to enhance emission efficiency, it is important to use a substance having a small work function for a cathode. Therefore, typically, the counter electrode 240 is formed of a metal film such as Mg—Ag or Al—Li and used as a cathode.

The organic EL layer 230 is a laminate containing various organic thin films. In the example shown in the figure, the organic EL layer 230 includes a hole injection layer 231 formed of a hole injecting organic substance (for example, a triphenylamine derivative), which is provided so as to improve hole injection efficiency from the anode, a light emitting layer 232 formed of a light emitting organic substance (for example, anthracene), and an electron injection layer 233 formed of an electron injecting material (for example, a perylene derivative), which is provided so as to improve electron injection efficiency from the cathode. The organic EL layer 230 is not limited to the example shown in the figure, and any suitable combination of organic thin films may be adopted as long as the light emitting layer 232 may emit light by recombination of electrons and holes. There may be adopted, for example, a configuration including a first hole transport layer (made of copper phthalocyanine or the like), a second hole transport layer (made of N,N′-diphenyl-N,N′-dinaphthylbenzidine or the like), and an electron transport and light emitting layer (made of tris(8-hydroxyquinolinato)aluminum or the like).

When a voltage at a threshold value or more is applied across the transparent electrode and the counter electrode, holes are supplied from the anode and reach the light emitting layer 232 through the hole injection layer 231. On the other hand, electrons are supplied from the cathode and reach the light emitting layer 232 through the electron injection layer 233. Energy generated by recombination of the holes and the electrons in the light emitting layer 232 excites a light-emitting organic substance in the light emitting layer, and the excited light-emitting organic substance radiates light when returning to a ground state to emit light. By applying a voltage to each desired pixel to cause the organic EL layer to emit light, an image can be displayed. In the case of performing color display, for example, light emitting layers of three adjacent pixels may be respectively formed of light-emitting organic substances for emitting red (R) light, green (G) light, and blue (B) light, or any suitable color filter may be provided on the light emitting layer.

In such an organic EL element, it is preferred that a thickness of the organic EL layer 230 be as small as possible. This is because it is preferred that the organic EL layer 230 transmit emitted light as much as possible. The organic EL layer 230 can be formed of a film having a thickness of, for example, 50 nm to 200 nm. Further, the organic EL layer may be formed of an extremely thin film having a thickness of, for example, about 10 nm.

<D. Lighting Device>

A lighting device according to one embodiment of the present invention includes the above-mentioned organic EL device. As described above, the organic EL device of the present invention enhances light extraction efficiency by using a light diffusing element containing a concentration adjusted area (as a result, a refractive index adjusted area). Therefore, even when the organic EL device is used outdoors, degradation in light extraction efficiency with the passage of time can be suppressed. Further, the light diffusing element used in the present invention does not require a complicated production step and can also be enlarged. Thus, the organic EL device of the present invention is also applicable to a large lighting device.

### EXAMPLES

The present invention is further described by way of examples and comparative examples described below. Note that, the present invention is not limited to these examples. Each analysis method used in the examples is as follows.

### (1) Presence or Absence of First Concentration Adjusted Area and Second Concentration Adjusted Area

A laminate of the light diffusing element and the base material obtained in each of the reference examples was sliced so as to have a thickness of 0.1 μm with a microtome while being cooled with liquid nitrogen to obtain a measurement sample. The state of fine particles in a light diffusing element portion of the measurement sample and the state of an interface between the fine particles and the matrix were observed with a transmission electron microscope (TEM). The case where the interface between the fine particles and the matrix was unclear was defined as “first concentration adjusted area is present” and the case where the interface between the fine particles and the matrix was clear was defined as “first concentration adjusted area is absent”. Further, the case where a contrast caused by the permeation of a precursor in an inner portion of the fine particles was able to be confirmed was defined as “second concentration adjusted area is present” and the case where a contrast was not able to be confirmed in an inner portion of the fine particles and uniform color was recognized was defined as “second concentration adjusted area is absent”.

### (2) Oblique Brightness:

Brightness at a polar angle of 60° and an azimuth angle of 45° measured manually was measured with Conoscope 850 (manufactured by Opto Design Inc.). As the brightness is higher, it is shown that the measurement sample has more satisfactory brightness even in an oblique direction.

### (3) Luminous Flux:

The brightness at a whole angle measured using Conoscope 850 (manufactured by Opto Design Inc.) was multiplied by case to obtain a value integrated to an angle of 0° to 90°. A larger value shows more satisfactory light extraction efficiency.

### (4) Color Change:

A movement distance from a front surface to a polar angle of 60° and an azimuth angle of 45° in an xy chromaticity diagram was obtained by the following expression. A smaller value shows a smaller change in color.

Movement distance from front surface to polar angle of 60° and azimuth angle of 45°=√{(X_{0°,0°}−X_{60°,45°})²+(Y_{0°,0°}−Y_{60°,45°})²}

### Production of Light Diffusing Element

### Reference Example 1

To 100 parts of a hard coat resin (“Opstar KZ6661” (trade name) (containing MEK/MIBK), manufactured by JSR Corporation) containing 62% zirconia nano particles (average particle diameter: 60 nm, refractive index: 2.19) as an ultrafine particle component, 11 parts of a 50% methyl ethyl ketone (MEK) solution of pentaerythritol triacrylate (“Biscoat #300” (trade name), refractive index: 1.52, manufactured by OSAKA ORGANIC CHEMICAL INDUSTRY LTD.) as a precursor of a resin component, 0.5 part of a photopolymerization initiator (“Irgacure 907” (trade name), manufactured by Ciba Specialty Chemicals Inc.), 0.5 part of a leveling agent (“GRANDIC PC 4100” (trade name), manufactured by DIC Corporation), and 15 parts of polymethyl methacrylate (PMMA) fine particles (“XX 131 AA” (trade name), average particle diameter: 2.5 μm, refractive index: 1.49, manufactured by SEKISUI CHEMICAL CO., LTD.) as light diffusing fine particles were added, and MIBK was added so that a solid content became 55% by weight. This mixture was subjected to ultrasonic treatment for 5 minutes to prepare an application liquid in which the above-mentioned respective components were dispersed uniformly. Immediately after the application liquid was prepared, the application liquid was applied onto a TAC film (“KC4UY” (trade name), thickness: 40 μm, manufactured by Konica Minolta Holdings Inc.) with a bar coater, dried at 100° C. for 1 minute, and irradiated with UV light with an integrated light quantity of 300 mJ to obtain a light diffusing element with a thickness of 10.5 μm. The diffusion half-value angle of the obtained light diffusing element was 60°, and a haze thereof was 97%.

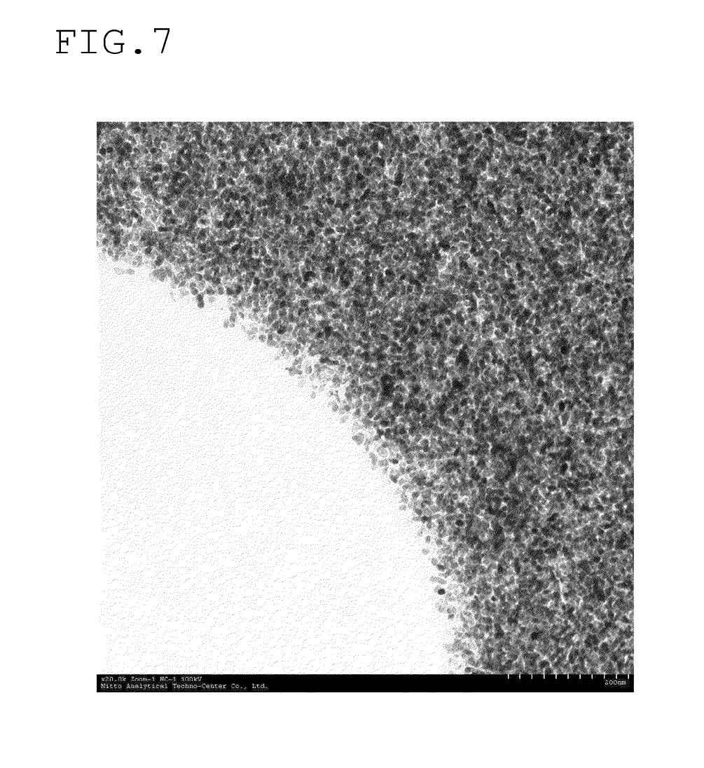

The refractive index of the matrix excluding the fine particles of the obtained light diffusing element was 1.61. FIG. 7 shows a cross-sectional TEM photograph in which the presence or absence of a concentration adjusted area of the obtained light diffusing element was confirmed. When the cross-sectional TEM photograph (direct magnification: ×50,000) was observed, a concentration adjusted area (first concentration adjusted area) of about 40 nm to 200 nm in which a refractive index changed step by step or substantially continuously was confirmed in the vicinity of the interface between the light diffusing fine particles and the matrix.

### Production of Light Diffusing Element

### Reference Example 2

Alight diffusing element was obtained in the same way as in Reference Example 1, except for applying an application liquid so that the thickness of the light diffusing element became 15 μm. The diffusion half-value angle of the obtained light diffusing element was 70°, and a haze thereof was 98%.

The refractive index of the matrix excluding the fine particles of the obtained light diffusing element was 1.61. When the cross-sectional TEM photograph (direct magnification: ×50,000) was observed for presence or absence of a concentration adjusted area of the obtained light diffusing element, a concentration adjusted area (first concentration adjusted area) of about 40 nm to 200 nm in which a refractive index changed step by step or substantially continuously was confirmed in the vicinity of the interface between the light diffusing fine particles and the matrix.

### Production of Organic EL Device

### Example 1

As an organic EL element, an element having the following configuration was used.

Glass (thickness: 1,000 μm)/cathode (Al, thickness: 120 nm)/charge injection-light emission-charge transport layer (thickness: 130 nm)/charge generating layer (thickness: 4 nm)/charge injection-light emission-charge transport layer (thickness: 85 nm)/charge generating layer (thickness: 3 nm)/charge injection-light emission-charge transport layer (thickness: 85 nm)/anode (ITO, thickness: 460 nm)/glass (thickness: 1,000 μm)

By bonding the light diffusing element obtained in Reference Example 1 to a light emitting surface side of the above-mentioned organic EL element via a pressure-sensitive adhesive, an organic EL device was obtained. The obtained organic EL device was caused to emit light at 13 V and 1 A, and oblique brightness, luminous flux, and color change were measured. Table 1 shows the characteristics of the obtained organic EL device.

### Example 2

An organic EL device was produced in the same way as in Example 1, except for using the light diffusing element obtained in Reference Example 2 as a light diffusing element. Table 1 shows the characteristics of the obtained organic EL device.

### Comparative Example 1

An organic EL device was produced in the same way as in Example 1, except that the light diffusing element was not used (only the organic EL element was used). Table 1 shows the characteristics of the obtained organic EL device.

### Comparative Example 2

An organic EL device was produced in the same way as in Example 1, except for bonding a microlens array (manufactured by Opto Science, Inc., a polystyrene resin on the surface of which has spheres having a radius of 15 μm) to an organic EL element, instead of the light diffusing element obtained in Reference Example 1. Table 1 shows the characteristics of the obtained organic EL device.

### Comparative Example 3

An organic EL device was produced in the same way as in Example 1, except for bonding a diffusion plate (ZEONOR resin provided with a wedge (reverse pyramid type) surface shape having a bottom of 80 μm square and a height of 56 μm) to an organic EL element, instead of the light diffusing element obtained in Reference Example 1. Table 1 shows the characteristics of the obtained organic EL device.

### Comparative Example 4

An organic EL device was produced in the same way as in Example 1, except for bonding a diffusion plate (“D114 series” (trade name) manufactured, by TSUJIDEN Co., Ltd., ZEONOR film with acryl beads applied thereto) to an organic EL element, instead of the light diffusing element obtained in Reference Example 1. Table 1 shows the characteristics of the obtained organic EL device.

TABLE 1

| | | Evaluation | | |
|---|---|---|---|---|
| | Light diffusing | Oblique | | |
| | element | brightness | | |
| | Type | (cd/m²) | Luminous flux | Color change |
| Example 1 | Internal | 3,035 | 11,300 | 0.0058 |
| | refractive index | | | |
| | adjustment | | | |
| Example 2 | Internal | 3,006 | 10,080 | 0.0051 |
| | refractive index | | | |
| | adjustment | | | |
| Comparative | None | 2,420 | 7,206 | 0.0220 |
| Example 1 | | | | |
| Comparative | External shape | 2,685 | 9,212 | 0.0191 |
| Example 2 | | | | |
| Comparative | External shape | 2,893 | 8,210 | 0.0148 |
| Example 3 | | | | |
| Comparative | Internal | 2,800 | 8,500 | 0.0092 |
| Example 4 | scattering | | | |

[Evaluation]

As is apparent from Table 1, in the organic EL devices of Examples and 2 each using the light diffusing element containing a concentration adjusted area, light in an oblique direction confined in the organic EL device exceeding a critical angle can be extracted without generating any loss caused by scattering, and thus, light extraction efficiency (luminous flux) was enhanced. Further, the brightness in an oblique direction was also improved, and colors of light in various directions were mixed, and hence, color change was also able to be suppressed.

On the other hand, in Comparative Example 1 having no light diffusing element, light extraction efficiency was not enhanced, oblique brightness was small, and color change was large. Further, in Comparative Examples 2 and 3 each having a diffusion layer provided with fine voids outside, light in an oblique direction was extracted as it was, and thus, light extraction efficiency was enhanced. However, brightness in an oblique direction was small, and color change was large. In Comparative Example 4 using a diffusion plate having diffusion performance by containing fine particles, color change was suppressed by color mixture in the diffusion plate. However, backscattering was not suppressed, and hence, brightness in an oblique direction was small, and light extraction efficiency was not obtained sufficiently.

### INDUSTRIAL APPLICABILITY

The organic EL device of the present invention is used for any suitable application, and can be used preferably in a lighting device, a backlight, various display apparatuses, or the like.

### REFERENCE SIGNS LIST

10 matrix
11 resin component
12 ultrafine particle component
20 light diffusing fine particle
31 concentration adjusted area (first concentration adjusted area)
32 second concentration adjusted area
100 light diffusing element
200 organic EL element
300 organic EL device

1. An organic EL device, comprising:
an organic EL element; and
a light diffusing element arranged on a light emitting surface side of the organic EL element,
wherein the light diffusing element includes a matrix containing a resin component and an ultrafine particle component, and light diffusing fine particles dispersed in the matrix,
wherein refractive indices of the resin component, the ultrafine particle component, and the light diffusing fine particle satisfy the following expression (1), and
wherein the light diffusing element includes a concentration adjusted area formed outside a vicinity of a surface of the light diffusing fine particle, in which a weight concentration of the resin component decreases and a weight concentration of the ultrafine particle component increases as a distance from the light diffusing fine particle increases,

|n_{P}−n_{A}|<|n_{P}−n_{B}| (1)
where n_{A} represents a refractive index of the resin component of the matrix, n_{B} represents a refractive index of the ultrafine particle component of the matrix, and n_{P} represents a refractive index of the light diffusing fine particle.

2. An organic EL device according to claim 1, further comprising a second concentration adjusted area which is formed through permeation of the resin component into an inside of the vicinity of the surface of the light diffusing fine particle.

3. An organic EL device according to claim 1, wherein the light diffusing element has a haze of 90% to 99%.

4. An organic EL device according to claim 1, wherein the light diffusing element satisfies 0.01≦|n_{P}−n_{A}|≦0.10 and 0.10≦|n_{P}−n_{B}|≦1.50.

5. An organic EL device according to claim 1,
wherein the resin component and the light diffusing fine particle are formed of materials of the same type, and
wherein the ultrafine particle component is formed of a material of a type different from the type of the resin component and the light diffusing fine particle.

6. An organic EL device according to claim 5,
wherein the resin component and the light diffusing fine particle are formed of organic compounds, and
wherein the ultrafine particle component is formed of an inorganic compound.

7. An organic EL device according to claim 1, wherein the light diffusing fine particle has an average particle diameter of 1 μm to 5 μm.

8. An organic EL device according to claim 1, wherein the ultrafine particle component has an average particle diameter of 1 nm to 100 nm.

9. An organic EL device according to claim 1, wherein the light diffusing element has a diffusion half-value angle of 10° to 150°.

10. Alighting device using the organic EL device according to claim 1.
